(19) United States
(12) Patent Application Publication
(10) Pub. No.: US 2022/0158059 A1
(43) Pub. Date: May 19, 2022

(54) DISPLAY PANEL AND DISPLAY DEVICE

(71) Applicant: KunShan Go-Visionox Opto-Electronics Co., Ltd., Kunshan (CN)

(72) Inventors: Yu JIN, Kunshan (CN); Enlai WANG, Kunshan (CN); Rulong LI, Kunshan (CN); Wangfeng XI, Kunshan (CN); Jijun JIANG, Kunshan (CN); Yunlei LU, Kunshan (CN)

(73) Assignee: KunShan Go-Visionox Opto-Electronics Co., Ltd., Kunshan (CN)

(21) Appl. No.: 17/588,720

(22) Filed: Jan. 31, 2022

Related U.S. Application Data
(63) Continuation of application No. PCT/CN2021/070158, filed on Jan. 4, 2021.

(30) Foreign Application Priority Data
Feb. 26, 2020 (CN) 202010119715.4

(51) Int. Cl. H01L 33/62; H01L 33/38; H01L 27/15; H01L 33/42

(52) U.S. Cl. CPC H01L 33/62; H01L 33/42; H01L 27/156; H01L 33/382

(57) ABSTRACT

A display panel and a display device. The display panel includes a transition region and a light-transmitting region, and a light transmittance of the light-transmitting region is greater than a light transmittance of the transition region. The display panel includes a driving backplane including a first driving circuit disposed in the transition region, a planarization layer disposed on the driving backplane of the transition region and the light-transmitting region, a first electrode layer disposed at a side of the planarization layer of the transition region and the light-transmitting region, and a plurality of first light-emitting units disposed in the light-transmitting region. The first electrode layer is electrically connected with the first output terminal by extending through the planarization layer, and is configured to provide electrical signals for the plurality of first light-emitting units.

### CROSS REFERENCE TO RELATED APPLICATIONS

The present application is a continuation of international application No. PCT/CN2021/070158 filed on Jan. 4, 2021, and claims priority to Chinese patent application No. 202010119715.4, entitled “DISPLAY PANEL, DISPLAY DEVICE AND METHOD FOR MANUFACTURING DISPLAY PANEL” filed Feb. 26, 2020, which is incorporated by reference herein in its entirety.

### TECHNICAL FIELD

Embodiments of the present disclosure relates to the field of display technology, in particular to a display panel and a display device.

### BACKGROUND

A screen-to-body ratio of electronic equipment has always been a major concern for users and manufacturers. The screen-to-body ratio generally refers to a ratio of display screen area to front panel area of the electronic equipment. In order to meet the demand of large screen-to-body ratio, the concept of full display emerges. In order to realize a full display, a region of the display screen corresponding to a camera in the display panel is set with pixels for displaying images.

### SUMMARY

Some embodiments of the present disclosure provide a display panel and a display device, thereby improving the display performance of the display panel.

In order to solve the above technical problems, some embodiments of the present disclosure provide a display panel including a transition region and a light-transmitting adjacent to the transition region, a light transmittance of the light-transmitting region being greater than a light transmittance of the transition region, wherein the display panel includes: a driving backplane including a first driving circuit disposed in the transition region, the first driving circuit being provided with a first output terminal; a planarization layer disposed on the driving backplane of the transition region and the light-transmitting region; a first electrode layer disposed at a side, facing away from the driving backplane, of the planarization layer of the transition region and the light-transmitting region, wherein first electrode layer is electrically connected with the first output terminal by extending through the planarization layer; wherein the first electrode layer disposed in the light-transmitting region includes at least two electrode blocks and an electrode bridge connecting two adjacent electrode blocks; and a plurality of first light-emitting units disposed in the light-transmitting region, wherein each of the plurality of first light-emitting units is correspondingly disposed at a side, facing away from the driving backplane, of corresponding one of the at least two electrode blocks; the first electrode layer is configured to provide electrical signals for the plurality of first light-emitting units.

The display panel includes the transition region and the light-transmitting region adjacent to the transition region, and the light transmittance of the light-transmitting region is greater than the light transmittance of the transition region. The display panel corresponding to the transition region is provided with the first electrode layer for providing the electrical signals to the plurality of first light-emitting units in the light-transmitting region. Therefore, the display panel corresponding to the light-transmitting region may be configured for both image display and light transmission. The first electrode layer disposed in the light-transmitting region of the display panel includes the at least two electrode blocks and the electrode bridge connecting the two adjacent electrode blocks. Therefore, by optimizing an arrangement of the first electrode layer in the light-transmitting region, the first electrode layer is arranged across the plurality of first light-emitting units and provides the electrical signals for the plurality of first light-emitting units. In addition, there is one electrode layer (i.e., the first electrode layer) between the first light-emitting units and the planarization layer. Compared with a technical solution that there are two electrode layers between the first light-emitting unit and the planarization layer, the present embodiments removes one electrode layer, which is beneficial to simplifying the manufacturing process of the display panel and saving cost. Moreover, the present embodiments weakens bombardment of an electrode layer material on the planarization layer when forming the electrode layer, improves the interface performance of the planarization layer, and further can improve the quality and morphology of the first electrode layer, and can improve the performance of the display panel.

Some embodiments of the present disclosure further provide a display device including the display panel.

### BRIEF DESCRIPTION OF THE DRAWINGS

FIG. 1 is a schematic diagram of a top view of a display panel according to some embodiments of the present disclosure.

FIG. 2 is a schematic diagram of a partial cross-sectional view of the display panel in FIG. 1 cut along an YY1 direction.

FIG. 3 is a schematic diagram of another top view of a first electrode layer in a display panel according to some embodiments of the present disclosure.

FIG. 4 is a schematic diagram of a cross-sectional viewof a display panel according to some embodiments of the present disclosure.

FIG. 5 is a schematic structural diagram corresponding to a plurality of steps in a method for manufacturing a display panel according to some embodiments of the present disclosure.

FIG. 6 is a schematic structural diagram corresponding to a plurality of steps in a method for manufacturing a display panel according to some embodiments of the present disclosure.

FIG. 7 is a schematic structural diagram corresponding to a plurality of steps in a method for manufacturing a display panel according to some embodiments of the present disclosure.

FIG. 8 is a schematic structural diagram corresponding to a plurality of steps in a method for manufacturing a display panel according to some embodiments of the present disclosure.

FIG. 9 is a schematic structural diagram corresponding to a plurality of steps in a method for manufacturing a display panel according to some embodiments of the present disclosure.

### DETAILED DESCRIPTION

It can be known from the background technology that the performance of an existing display panel needs to be improved, for example, a photographing effect of a camera is poor. In order to increase a light transmittance of a light-transmitting region and improve the light collection effect of a light collection component of a camera in the light-transmitting region, a driving backplane of the light-transmitting region is generally not provided with a driving circuit, and light-emitting units in the light-transmitting region are provided with an electrical signal(s) from a driving circuit in a transition region. However, while improving the light transmittance of the light-transmitting region, it also faces a problem of an abnormal overlap between anodes of a main screen region and the transition region and output terminals of their driving circuits respectively, and there is also a problem of an Ag migration in the anodes of the main screen region and the transition region, resulting in an abnormal display of the main screen region and the transition region.

It is found that a conventional manufacturing method for a display panel includes: providing a transparent electrode layer in the light-transmitting region of the display panel. Taking the material of the transparent electrode layer being an ITO material as an example, a drain of the main screen region and a drain of the transition region may be exposed to an ITO-sputtering process environment and a patterning process environment, which may lead to changes in the physical and chemical properties of the drain surface material, thus causing changes in the physical and chemical properties of the material of drain surfaces, resulting in abnormal overlap between the drain and its corresponding anode.

In addition, the planarization layer of the transition region and the main screen region may also be exposed to the sputtering process environment for forming the transparent electrode layer. The ITO material may bombard a surface of the planarization layer, resulting in the deterioration of the surface performance of the planarization layer. When an anode containing the Ag is formed on the surface of the planarization layer later, the Ag in the anode easily migrates from the damaged surface of the planarization layer, resulting in a loose and uneven layer of Ag and an abnormal performance of the display panel.

In order to solve the above problems, some embodiments of the present disclosure provide a display panel. A first electrode layer disposed in a light-transmitting region of the display panel includes at least two electrode blocks and an electrode bridge connecting two adjacent electrode blocks. Therefore, by optimizing an arrangement of the first electrode layer in the light-transmitting region, the first electrode layer is arranged across a plurality of first light-emitting units and provides electrical signals for the plurality of first light-emitting units. In addition, there is only one electrode layer (i.e., the first electrode layer) between the first light-emitting units and the planarization layer. Compared with a technical solution that there are two electrode layers between the first light-emitting units and the planarization layer, the present disclosure removes one electrode layer, which is beneficial to simplifying the manufacturing process of the display panel and saving cost. Moreover, the present disclosure weakens a bombardment of a material of an electrode layer on the planarization layer when forming the electrode layer, improves the interface performance of the planarization layer, and further can improve the quality and morphology of the first electrode layer, and can improve the performance of the display panel.

The embodiments of the present disclosure will be described in detail below with reference to the accompanying drawings in order to make the objectives, technical solutions and advantages of the present disclosure clearer. However, it will be apparent to those skilled in the art that, in the various embodiments of the present disclosure, numerous technical details are set forth in order to provide the reader with a better understanding of the present disclosure. However, the technical solutions claimed in the present disclosure may be implemented without these technical details and various changes and modifications based on the following embodiments. The following embodiments are divided for convenience of description, and should not constitute any limitation to the specific implementation of the present disclosure. The various embodiments may be combined with each other and referred to each other on the premise of no contradiction.

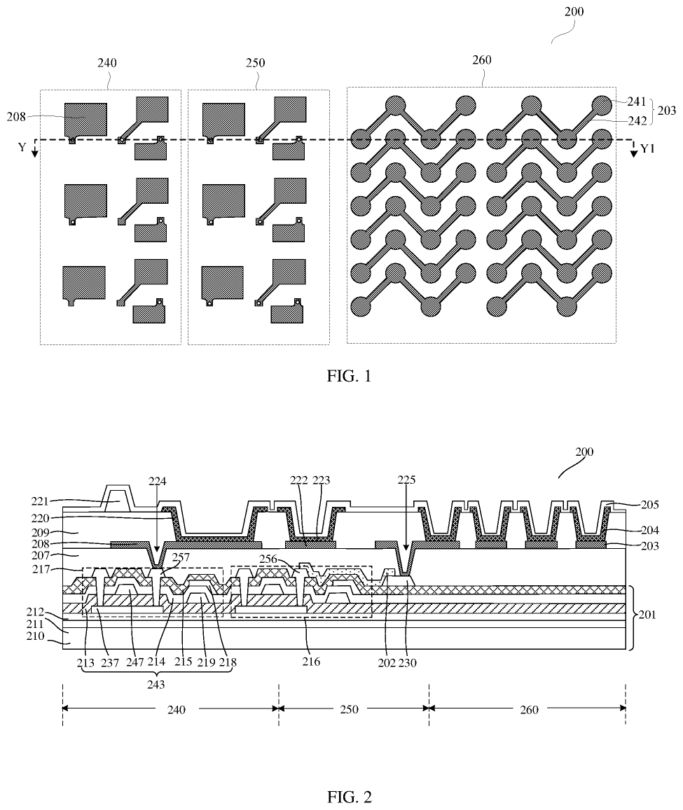

FIG. 1 is a schematic diagram of a top view of a display panel according to some embodiments of the present disclosure, and FIG. 2 is a schematic diagram of a partial cross-sectional view of the display panel in FIG. 1 cut along an YY1 direction.

As shown in FIGS. 1 and 2, a display panel 200 is provided with a transition region 250 and a light-transmitting region 260 adjacent to each other, and a light transmittance of the light-transmitting region 260 is greater than a light transmittance of the transition region 250. The display panel 200 includes: a driving backplane 201, a planarization layer 207, a first electrode layer 203 and a plurality of first light-emitting units 204 disposed in the light-transmitting region 260. The driving backplane 201 includes a first driving circuit 216 disposed in the transition region 250, and the first driving circuit 216 is provided with a first output terminal 256. The planarization layer 207 is disposed on the driving backplane 201 of the transition region 250 and the light-transmitting region 260. The first electrode layer 203 is disposed at a side, facing away from the driving backplane 201, of the planarization layer 207 of the transition region 250 and the light-transmitting region 260, and the first electrode layer 203 is configured to extend through the planarization layer 207 to be electrically connected with the first output terminal 256. The first electrode layer 203 disposed in the light-transmitting region 260 includes at least two electrode blocks 241 and an electrode bridge 242 connecting two adjacent electrode blocks 241. Each of the plurality of first light-emitting units 204 is correspondingly disposed at a side, which is facing away from the driving backplane 201, of each electrode block 241, and the first electrode layer 203 is used for providing electrical signals for the plurality of first light-emitting units 204.

The display panel according to these embodiments will be described in detail with reference to the accompanying drawings.

The display panel 200 includes a main screen region 240, the transition region 250 and the light-transmitting region 260. The transition region 250 is disposed between the main screen region 240 and the light-transmitting region 260.

The main screen region 240, the transition region 250 and the light-transmitting region 260 all have an image display function. The light transmittance of the light-transmitting region 260 is greater than the light transmittance of the main screen region 240 and the light transmittance of the transition region 250. The light transmittance of the main screen region 240 and the light transmittance of the transition region 250 may be the same. The light-transmitting region 260 may be used for both displaying image and transmitting light. Therefore, it facilitates to set a light collection component of a camera in the light-transmitting region 260, so that the light collection component of the camera can receive enough light while ensuring a high screen-to-body ratio, thereby improving the photographing effect.

The driving backplane 201 includes a substrate 210 and a driving component layer 243 on the substrate 210.

In this embodiment, the display panel 200 may be applied to a flexible display device, and the substrate 210 is a flexible substrate accordingly. A material of the flexible substrate is a polyethylene (PE), a polypropylene (PP), a polystyrene (PS), a polyethylene terephthalate (PET), a polyethylene naphthalate (PEN) or a polyimide (PI). The substrate 210 may be an ultra-thin glass substrate, and a thickness of the ultra-thin glass substrate is less than 50 μm. It can be understood that in other embodiments, the substrate may be a rigid substrate, such as a rigid glass.

The driving component layer 243 provides driving signals for the light-emitting units in the display panel 200 to emit light. The driving component layer 243 includes a plurality of layers and includes: an active layer 237 and a gate structure disposed on the active layer 237, the gate structure including a gate dielectric layer 213 and a gate electrode layer 247 disposed on the gate dielectric layer 213; a source in the active layer 237 disposed at one side of the gate structure, a drain in the active layer 237 disposed at the other side of the gate structure; a first capacitor conductive layer 219 disposed on the gate dielectric layer 213; a capacitor dielectric layer 214 covering the gate structure, the first capacitor conductive layer 219 and the active layer 237; a second capacitor conductive layer 218 disposed on the capacitor dielectric layer 214 and directly opposite to the first capacitor conductive layer 219 to form a storage capacitor; an insulating dielectric layer 215 covering the capacitor dielectric layer 214 and the second capacitor conductive layer 218; a source electrode and a drain electrode extending through the insulating dielectric layer 215, the capacitor dielectric layer 214, and the gate dielectric layer 213, wherein the source electrode is electrically connected to the source, the drain electrode is electrically connected to the drain.

In this embodiment, the driving component layer 243 has a thin film transistor (TFT) and the storage capacitor. The thin film transistor may be a low temperature poly-silicon (LTPS) thin film transistor. It can be understood that the driving device layer 243 may also include other film layer structures, and the above merely lists the structure of the thin film transistor as an example.

The driving component layer 243 is used to form a driving circuit. The driving circuit may include at least one thin film transistor and at least one storage capacitor. The thin film transistor may be a switch transistor and/or a drive transistor. In this embodiment, there is no driving circuit in the driving component layer 243 of the light-transmitting region 260, so as to meet the requirement of high light transmittance of the light-transmitting region 260. That is, the driving component layer 243 of the light-transmitting region 21 does not have the thin film transistor and the storage capacitor. The driving device layer 243 of the transition region 250 is provided with a first driving circuit 216, and the first driving circuit 216 is provided with a first output terminal 256. In this embodiment, the first output terminal 256 is a drain electrode of the thin film transistor of the first driving circuit 216.

In this embodiment, the driving backplane 210 further includes a second driving circuit (not shown) disposed in the transition region 250. The second driving circuit is provided with a second output terminal, and the second driving circuit is used for providing electrical signals for the light emitting units of the transition region 250. The driving backplane 201 may further include a third driving circuit 217 disposed in the main screen region 240, and the third driving circuit 217 is provided with a third output terminal 257. The third output terminal 257 may be a drain electrode of the thin film transistor of the third driving circuit 217 for providing electrical signals for the light-emitting units of the main screen region 240.

In this embodiment, the display panel 200 further includes an electrical connection portion 230 disposed at a side, which is facing to the driving backplane 201, of the planarization layer 207 of the transition region 250. A material of the electrical connection portion 230 is a conductive material, such as a metal material. In addition, the material of the electrical connection portion 230 may be the same as a material of the first output terminal 256.

In this embodiment, the display panel 200 further includes an electrical connection layer 202. The electrical connection layer 202 is disposed at the side, which is facing to the driving backplane, of the planarization layer 207 of the transition region 250, and the electrical connection layer 202 is used for electrically connecting the electrical connection portion 230 with the first output terminal 256. The first electrode layer 203 is electrically connected to the first output terminal 256 through the electrical connection portion 230 and the electrical connection layer 202. The first driving circuit 216 of the transition region 250 is used to provide the electrical signals for the first light-emitting units 204 of the light-transmitting region 260. That is, the light-transmitting region 260 is not provided with a driving circuit, so that the light transmittance of the light-transmitting region may be improved on the premise of ensuring that the light-transmitting region 260 has a display function.

A light transmittance of the electrical connection layer 202 is greater than a light transmittance of the first electrode layer 203. A material of the electrical connection layer 202 is a transparent electrode material, such as ITO or IZO. A thickness of the electrical connection layer 202 is 280-340 angstroms, such as 300 angstroms and 320 angstroms. In other embodiments, the material of the electrical connection layer may also be at least one of Mg/Ag alloy, Al, Li, Ca and In.

In this embodiment, the display panel 200 further includes the planarization layer 207 disposed on the driving backplane 201 of the main screen region 240, the transition region 250 and the light-transmitting region 260.

The planarization layer 207 covers the driving backplane 201 of the main screen region 240 in addition to the driving backplane 201 of the light-transmitting region 260 and the driving backplane 201 of the transition region 250. On one hand, the planarization layer 207 may provide a surface with a high flatness. On the other hand, the planarization layer 207 may further provide an interface for the first electrode layer 203.

A material of the planarization layer 207 is a transparent material. The transparent material may be an inorganic transparent material such as a silicon oxide. Alternately, the transparent material may be an organic transparent material such as the polyimide. In this embodiment, the material of the planarization layer 207 is the polyimide.

The planarization layer 207 disposed in the transition region 250 is provided with a first through hole 225 extending through the planarization layer 207, and the first through hole 225 exposes a part of the surface of the electrical connection portion 230.

In this embodiment, the display panel 200 further includes the first electrode layer 203 and the plurality of first light-emitting units 204 in contact with the first electrode layer 203.

Herein, the first electrode layer 203 is disposed at the side, which is facing away from the driving backplane 201, of the planarization layer 207 of the transition region 250 and the light-transmitting region 260. The first electrode layer 203 contacts with the electrical connection portion 230 by extending through the planarization layer 207. In one example, at least a part of the first electrode layer 203 is disposed in the first through hole 225, and is in contact with the electrical connection portion 230 exposed by the first through hole 225. The electrical connection portion 230 is electrically connected with the first output terminal 256 through the electrical connection layer 202, thereby realizing an electrical connection between the first electrode layer 203 and the first output terminal 256. In addition, since the first electrode layer 203 electrically contacts with the plurality of first light-emitting units 204, the first output terminal 256 may achieve to control the plurality of first light-emitting units 204 to work, thereby realizing the image display function of the light-transmitting region 260.

The driving backplane 201 of the light-transmitting region 260 is not provided with a driving circuit, and the first light-emitting units 204 of the light-transmitting region 260 is electrically connected with the first driving circuit 216 of the transition region 250 to realize the image display function. Therefore, blocking or reflecting the light incident into the light-transmitting region 260 due to the driving circuit may be prevented, so that the light transmittance of the display panel 200 in the light-transmitting region 260 is improved, and more light may be received by the light collection component of the camera disposed in the light-transmitting region 260. That is, light collection amount of the light collection component of the camera may be improved, thereby improving the photographing effect and quality of the camera.

In addition, in an existing technical solution, the light-transmitting region includes a plurality of driving circuits. The planarization layer is provided with a plurality of through holes extending through the planarization layer and exposing each driving circuit, and each through hole is provided with an electrode layer connected with each light-emitting unit. That is, discrete electrode layers are respectively disposed in the plurality of through holes, and each electrode layer provides an electrical signal for each light-emitting unit corresponding to the electrode layer. That is, in this technical solution, the planarization layer of the light-transmitting region is provided with a plurality of through holes, and a filling material in the through holes is different from a material of the planarization layer. Since the material in the through hole is different from a material of the planarization layer, the refractive index of the material of the through hole is also different from the refractive index of the material of the planarization layer. When light passes through the light-transmitting region, a transmission direction of the light passing through the through hole is different from a transmission direction of the light passing through other regions of the planarization layer. That is, the transmission directions of the light reaching the light collection component of the camera are varied, which may cause an obvious diffraction problem, thus affecting the photographing effect of the camera. However, in this embodiment, there is no through hole in the planarization layer 207 of the light-transmitting region 260, and the thickness of the planarization layer 207 of the light-transmitting region 260 is uniform. That is, the material of the planarization layer 207 of the light-transmitting region 260 is uniform and homogeneous. There is no obvious difference in the refractive indexes of lights incident on the planarization layer 207, that is, the planarization layer 207 of the light-transmitting region 260 has a uniform refraction effect for light in different regions, and then the transmission direction of the light passing through the planarization layer 207 tends to be uniform, so that the transmission directions of the light received by the light collection component of the camera are approximately the same, which may avoid the diffraction problem of the light in the light-transmitting region 260, thereby improving the photographing effect.

In this embodiment, the first electrode layer 203 includes a first transparent electrode layer (not shown), a metal electrode layer (not shown) and a second transparent electrode layer (not shown) which are sequentially stacked. Therefore, the first electrode layer 203 may be used as a fully reflective layer forming an optical microcavity in the display panel, and form the optical microcavity with the first light-emitting unit 204, so that a chromaticity coordinate of the light-transmitting region 260 tends to a standard chromaticity coordinate.

A material of the first transparent electrode layer and a material of the second transparent electrode layer include an indium tin oxide (ITO) or a zinc tin oxide (IZO). A material of the metal electrode layer includes at least one of Mg, Ag and Al. In one example, the first electrode layer 203 may have a laminated structure of ITO layer/Ag layer/ITO layer. In one example, the first electrode layer may also be a single-layer structure or a laminated structure. In this embodiment, the first electrode layer 203 is an anode.

In this embodiment, the display panel 200 further includes the first electrode layer 203 and the first light-emitting units 204 disposed in the light-transmitting region 260.

As shown in FIG. 1, the first electrode layer 203 disposed in the light-transmitting region 260 includes at least two electrode blocks 241 and an electrode bridge 242 connecting two adjacent electrode blocks 241. With regard to the structures of the electrode block 241 and the electrode bridge 242, reference may be made according to the foregoing description of the first electrode layer 203.

In this way, the two adjacent electrode blocks 241 are electrically connected through the electrode bridge 242, so that at least two first light-emitting units 204 in the light-transmitting region 260 may share the same driving circuit. Since the space occupied by the electrode bridge 242 is small, the transmittance requirement of the light-transmitting region 260 may be met. Further, since the first electrode layer 203 is a laminated structure containing Ag, the first electrode layer 203 provides a semi-transparent and semi-reflective film to form the optical microcavity for the light-transmitting region 260. That is to say, in this embodiment, the display panel 200 corresponding to the light-transmitting region 260 has the optical microcavity, so that a cavity length difference among the light-transmitting region 260, the main screen region 240 and the transition region 250 is small, thereby improving a chromaticity coordinate consistency of the light-transmitting region 260, the main screen region 240 and the transition region 250, and further improving the display effect of the display panel.

Each first light-emitting unit 204 is correspondingly disposed on the side, which is facing away from the driving backplane 201, of each electrode block 241. An orthographic projection of the electrode bridge 242 on the driving backplane 201 is at least disposed in a region between two orthographic projections of two adjacent first light-emitting units 204 on the driving backplane 201. That is, the electrode bridge 242 is at least disposed between two adjacent first light-emitting units 204. In one example, the orthographic projection of the first light-emitting unit 204 on the driving backplane 201 is larger than the orthographic projection of the electrode block 241 corresponding to the first light-emitting unit 204 on the driving backplane 201. That is, the size of the first light-emitting unit 204 is larger than the size of the electrode block 241 corresponding to the first light-emitting unit 204.

In addition, an area of the orthographic projection of the electrode bridge 242 on the driving backplane 201 is smaller than an area of the orthographic projection of the electrode block 241 on the driving backplane 201. That is, the size of the electrode bridge 242 is smaller than the size of the electrode block 241. In a direction orthogonal to a surface of the driving backplane 201 and perpendicular to an extending direction of the electrode bridge 242, a cross-sectional width of the electrode bridge 242 ranges from 1 μm to 4 μm, for example, 2 μm, 2.8 μm and 3 μm. Therefore, a luminous flux blocked by the electrode bridge when the light disposed at outside of the screen enters the display panel in the light-transmitting region may be reduced, and the light transmittance of the light-transmitting region may be improved.

Since the size of the electrode bridge 242 is smaller than the size of the electrode block 241, and the electrode bridge 242 is at least disposed between two adjacent first light-emitting units 204, it may be avoided that most of the light incident through a region between the two adjacent first light-emitting units 204 is blocked and reflected by the electrode bridge 242. That is, most of the light may be incident into the display panel 200 through the region between the two adjacent first light-emitting units 204, and the light transmittance of the display panel 200 in the light-transmitting region 260 is high, which is beneficial to improving the photographing effect of the camera disposed in the light-transmitting region 260. In addition, the size of the first light-emitting unit 204 is larger than the size of the electrode block 241 corresponding to the first light-emitting unit 204, which may prevent light from being blocked and reflected by the electrode block 241, thereby further improving the light transmittance of the display panel 200 in the light-transmitting region 260 and improving the photographing effect of the camera disposed in the light-transmitting region 260.

In this embodiment, a cross-sectional width of the electrode bridge 242 ranges from 2.5 μm to 3.5 μm in the direction orthogonal to a surface of the driving backplane 201 and perpendicular to an extending direction of the electrode bridge 242. In this way, while ensuring the high light transmittance of the light-transmitting region 260, it is beneficial to reduce the manufacturing process difficulty of the electrode bridge 242, such as reducing an etching difficulty of forming the electrode bridge 242 by a wet etching, and further ensuring that the electrode bridge 242 has a good morphology. In this way, it avoids an unnecessary electrical connection between the adjacent electrode bridges 242, thereby further improving the display effect of the display panel.

Each first electrode layer 203 includes at least two electrode blocks 241 and the electrode bridge 242 connecting the two adjacent electrode blocks 241.

In this embodiment, as shown in FIG. 1, there are three or more electrode blocks 241. The shape of the first electrode layer 203 disposed in the light-transmitting region 260 is a zigzag shape, and each electrode block 241 is at an inflection point of the zigzag shape. Therefore, the first light-emitting units 204 electrically connected to the same driving circuit are distributed in the zigzag shape, which may increase a pixel density of the light-transmitting region 260.

In order to further increase the pixel density of the light-transmitting region 260, the two adjacent electrode bridges 242 of the first electrode layers 203 are parallel. In this embodiment, a distance between the parallel electrode bridges 242 is greater than or equal to 5 μm, which is conducive to increasing the pixel density of the light-transmitting region 260, further increasing a light-transmitting area of the light-transmitting region 260, and further improving the light transmittance of the light-transmitting region 260.

In FIG. 2, for example, there are four first light-emitting units 204. That is, one first electrode layer 203 is electrically connected with four first light-emitting units 204. In other embodiments, one first electrode layer may be electrically connected with two, three or any number of first light-emitting units.

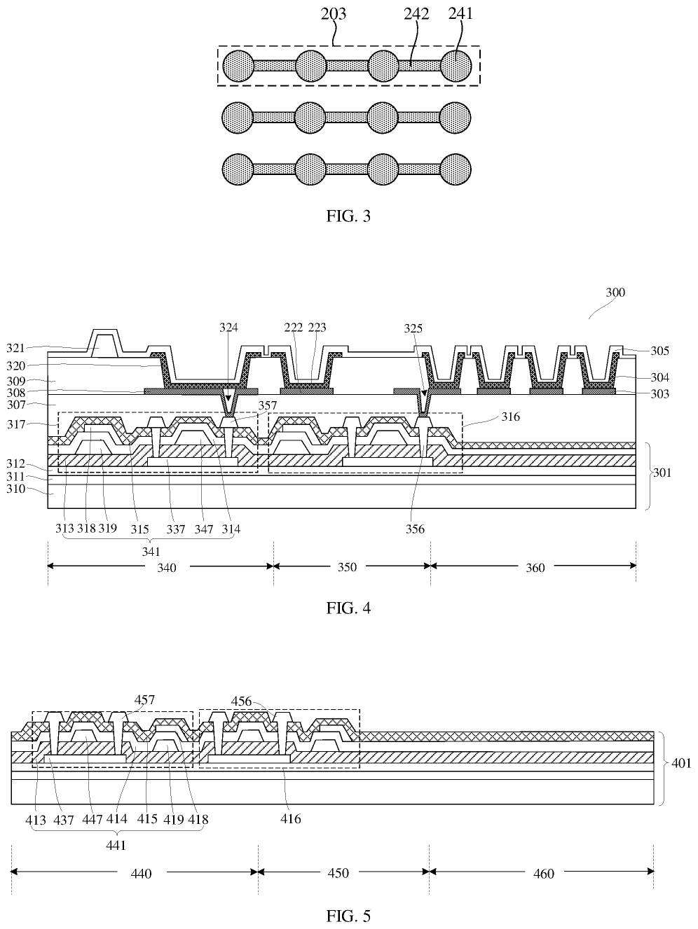

It can be understood that in other embodiments, the shape of the first electrode layer may be a regular straight line or an irregular connecting line. FIG. 3 is a schematic diagram of another top view of the display panel according to some embodiments of the present disclosure. As shown in FIG. 3, electrode blocks 241 and the electrode bridge 242 connecting two adjacent electrode blocks 241 are arranged along a regular straight line.

The first light-emitting unit 204 includes a hole inject layer (HIL), a hole transport layer (HTL) disposed on the hole inject layer, an emitting layer (EML) disposed on the hole transport layer, an electron transport layer (ETL) disposed on the emitting layer, and an electron inject layer (EIL) disposed on the electron transport layer.

The first light-emitting unit 204 may emit a red light, a blue light or a green light.

In this embodiment, there is only one electrode layer (i.e., the first electrode layer 203) disposed between the first light-emitting unit 204 and the planarization layer 207. Compared with a technical solution that there are two electrode layers between the first light-emitting unit 204 and the planarization layer 107, an ITO electrode layer is removed in the present disclosure, which is beneficial to simplifying the manufacturing process of the display panel 200 and saving cost.

Moreover, in this embodiment, there is only one electrode layer disposed between the first light-emitting unit 204 and the planarization layer 207, which avoids bombardment of the ITO on the planarization layer 207 and improves the interface performance of the planarization layer 207, and can further improve the quality and morphology of the first electrode layer 203 on the surface of the planarization layer 207, and can improve the performance of the display panel 200.

In this embodiment, the display panel 200 further includes: a second electrode layer 222 and a second light-emitting unit 223 disposed in the transition region 250. The second electrode layer 222 is disposed at a side, which is facing away from the driving backplane 201, of the planarization layer 207 of the transition region 250 and the second electrode layer 222 is electrically connected with a second output terminal (not labeled) by extending through the planarization layer 207. The second light-emitting unit 223 is disposed at a side, which is facing away from the driving backplane 201, of the second electrode layer 222. The second electrode layer 222 is used for providing an electrical signal for the second light-emitting unit 223. The second electrode layer 222 is disposed at the same layer as the first electrode layer 203. A material of the second electrode layer 222 is same as a material of the first electrode layer 203.

The planarization layer 207 of the transition region 250 is provided with a second through hole. The second through hole exposes a part of a surface of the second output terminal. At least part of the second electrode layer 222 is also disposed in the second through hole. The second output terminal of the second driving circuit is electrically connected with the second electrode layer 222 of the transition region 250, and provides the electrical signal for the second light-emitting unit 223 of the transition region 250, so as to realize the image display function of the transition region 250.

Further, the second electrode layer 222 and the first electrode layer 203 are disposed at the same layer, and a material of the second electrode layer 222 is same as a material of the first electrode layer 203. Therefore, the second electrode layer 222 may be formed by the same patterning process as the first electrode layer 203. That is, the second electrode layer 222 may be manufactured by the same process steps of manufacturing the first electrode layer 203, thereby simplifying the process steps and saving the manufacturing cost.

In this embodiment, the display panel 200 further includes: a third electrode layer 208 and a third light-emitting unit 220 disposed in the main screen region 240. The third electrode layer 208 is disposed at a side, which is facing away from the driving backplane 201, of the planarization layer 207 of the main screen region 240 and the third electrode layer 208 is electrically connected with a third output terminal 257 by extending through the planarization layer 207. The third light-emitting unit 220 is disposed at a side, which is facing away from the driving backplane 201, of the third electrode layer 208. The third electrode layer 208 is used for providing an electrical signal for the third light-emitting unit 220. The third electrode layer 208 and the first electrode layer 203 are disposed at the same layer. A material of the third electrode layer 208 is same as a material of the first electrode layer 203.

The third output terminal 257 of the third driving circuit 217 is electrically connected with the third electrode layer 208 of the main screen region 240 for providing the electrical signal to the third light-emitting unit 220 of the main screen region 240, so as to realize the image display function of the main screen region 240.

In one example, the planarization layer 207 disposed in the main screen region 240 is provided with a third through hole 224 corresponding to the first output terminal 257, and the third through hole 224 exposes a part of the surface of the first output terminal 257. At least a part of the third electrode layer 208 is disposed in the third through hole 224, and the third electrode layer 208 is electrically contact with the first output terminal 257 to provide the electrical signal for the third light-emitting unit 220.

Further, the third electrode layer 208 and the first electrode layer 203 are disposed at the same layer, and a material of the third electrode layer 208 is same as a material of the first electrode layer 203. Therefore, the third electrode layer 208 may be formed by the same patterning process as the first electrode layer 203. That is, the third electrode layer 208 may be manufactured by the same process steps of manufacturing the first electrode layer 203, thereby simplifying the process steps and saving the manufacturing cost.

In this embodiment, the display panel 200 further includes a fourth electrode layer 205 covering the first light-emitting units 204, the second light-emitting unit 223 and the third light-emitting unit 220. The fourth electrode layer 205 is a cathode, and the material of the fourth electrode layer 205 is the same as the material of the first electrode layer 203.

The plurality of electrode blocks 241 disposed in the light-transmitting region 260 and the fourth electrode layer 205 constitute a plurality of microcavities. The second electrode layer 222 and the fourth electrode layer 205 constitute microcavities. The third electrode layer 208 and the fourth electrode layer 205 constitute microcavities. That is, the light-transmitting region 260, the main screen region 240 and the transition region 250 all have microcavities, so that the light-transmitting region 260, the main screen region 240 and the transition region 250 have relatively close chromaticity coordinates, thereby ensuring that the chromaticity coordinates of the whole display panel 200 tend to be consistent, improving the color uniformity of the display panel 200 and further improving the display effect of the display panel 200.

In this embodiment, the display panel 200 further includes: a pixel defining layer 209 and a support post 221. The pixel defining layer 209 is disposed on a side, which is facing away from the driving backplane 201, of the planarization layer 207, and the pixel defining layer 209 is used for defining the positions of the first light-emitting unit 204, the second light-emitting unit and the third light-emitting unit. The support post 221 is disposed on a side, which is facing away from the driving backplane 201, of the pixel defining layer 209. The fourth electrode layer 205 covers the support post 221.

In this embodiment, the main screen region 240, the transition region 250 and the light-transmitting region 260 all have the image display function. The light transmittance of the light-transmitting region 260 is greater than the light transmittance of the main screen region 240 and the light transmittance of the transition region 250. That is, the light-transmitting region 260 may be used for both image display and light transmission. Therefore, it is convenient to set the light collection component of the camera in the light-transmitting region 260, so that the light collection component of the camera can receive enough light while ensuring the high screen-to-body ratio, thereby improving the photographing effect of the camera.

In addition, there is no driving circuit in the driving backplane of the light-transmitting region 260. The first driving circuit 216 of the transition region 250 is electrically connected with the first electrode layer 203 of the light-transmitting region 260 for providing the electrical signals to the plurality of first light-emitting units 204 electrically connected with the first electrode layer 203. Therefore, the light incident into the light-transmitting region 260 can be prevented from being reflected or blocked due to the driving circuit of the light-transmitting region 260. That is, the light transmittance of the light-transmitting region 260 can be improved, and the luminous flux received by the light collection component of the camera disposed in the light-transmitting region 260 can be improved, so that enough light can enter the light collection component of the camera, thereby improving the photographing effect and photographing quality of the camera.

In addition, there is only one electrode layer (i.e., the first electrode layer 203) disposed between the first light-emitting unit 204 and the planarization layer 207. Compared with the technical solution that there are two electrode layers between the first light-emitting unit 204 and the planarization layer 207, one electrode layer is removed in the present disclosure, which is beneficial to simplifying the manufacturing process of the display panel 200 and saving cost.

That is to say, there is no need to provide a transparent conductive material such as ITO on the side of the planarization layer 207 facing the driving backplane 201, so that the adverse effects caused by the process steps of forming the ITO can be avoided. The interface performance of the planarization layer 207 can be improved, and the quality and morphology of the first electrode layer 207 can be improved. For example, the damage to the second output terminal of the transition region 250 and the third output terminal 257 of the main screen region 240 caused by the process steps of forming the ITO can be avoided, thereby avoiding the abnormal overlapping problem and further improving the performance of the display panel 200.

Some embodiments of the present disclosure further provide a display panel. Different from the previous embodiments, in the display panel according to the embodiments, a first electrode layer disposed in a light-transmitting region is directly electrically connected with an electrical connection portion of a transition region, so as to provide electrical signals to a plurality of first light-emitting units. FIG. 4 is a schematic diagram of a cross-sectional view of a display panel according to some embodiments of the present disclosure.

As shown in FIG. 4, the display panel 300 includes a transition region 350, a light-transmitting region 360 and a main screen region 340 which are adjacent to each other. The display panel 300 includes a driving backplane 301, a driving component layer 341, a planarization layer 307, a fourth electrode layer 305, a pixel defining layer 309, and a support post 321.

The driving component layer 341 provides a driving signal for a light-emitting unit in the display panel 300 to emit light. The driving component layer 341 is a multilayer film structure and includes: an active layer 337, a gate dielectric layer 313, a gate electrode layer 347, a first capacitor conductive layer 319, a capacitor dielectric layer 314, a second capacitor conductive layer 318, and an insulating dielectric layer 315.

The driving component layer 341 of the transition region 350 is provided with a first driving circuit 316 and a second driving circuit (not shown). The first driving circuit 316 is provided with a first output terminal 356. The second driving circuit is provided with a second output terminal. The driving component layer 341 disposed in the main screen region 340 is provided with a third driving circuit 317, and the third driving circuit 317 is provided with a third output terminal 357.

In this embodiment, the planarization layer 307 is provided with a first through hole 325, a second through hole and a third through hole 324 respectively corresponding to the first output terminal 356, the second output terminal and the third output terminal 357. At least a part of the first electrode layer 303 is disposed in the first through hole 325 and is electrically connected with the first output terminal 356 through the first through hole 325, and is used for providing the electrical signals for a plurality of first light-emitting units 304 to realize an image display function of the light-transmitting region 360. At least a part of the third electrode layer 308 is disposed in the third through hole 324 and is electrically connected with the third output terminal 357 through the third through hole 324, and is used for providing the electrical signals for a plurality of third light-emitting units 320 to realize an image display function of the main screen region 340.

Compared with the previous embodiments, the embodiments changes an arrangement of the driving component layer 341. That is, the first output terminal 356 is closer to the light-transmitting region 360; and an electrical connection between the first electrode layer 303 and the first output terminal 356 may be realized without providing additional electrical connection portions and electrical connection layers. That is, the first electrode layer 303 is directly connected with the first output terminal 356. Therefore, the manufacturing process of electrical connection portions and other components of the transition region 350 is saved, which is beneficial to saving cost.

In addition, since the transition region 350 does not include components such as the electrical connection portion, a size of the driving backplane 301 may be reduced, and an integration degree of the driving backplane 301 may be improved, thus reducing a size of the display panel 300.

For the same or corresponding parts as the previous embodiment, please refer to the previous embodiment in detail, which will not be repeated in detail below.

Correspondingly, some embodiments of the present disclosure further provide a display device, including the display panel in any of the foregoing embodiments. The display device may be a product or assembly with a TV function such as a mobile phone, a tablet computer, a TV set, a display, a digital photo frame, or a navigator.

Further, the display device further includes a light collection component. The light collection component is disposed corresponding to the position of the light-transmitting region, and the light collection component may be a camera or a fingerprint recognition chip or the like.

Some embodiments of the present disclosure further provide a method for manufacturing a display panel, which may be applied to the above-mentioned display panel. The method for manufacturing the display panel according to some embodiments of the present disclosure will be described in detail below with reference to the accompanying drawings. For the same or corresponding parts as the above embodiments, reference may be made to the detailed description of the above embodiments, which will not be repeated here.

The method for manufacturing the display panel according to some embodiments of the present disclosure will be described in detail below with reference to FIGS. 5 to 9.

In step 51, as shown in FIG. 5, a driving backplane 401 is provided. The driving backplane 401 includes a main screen region 440, a transition region 450, and a light-transmitting region 460. The transition region 450 is disposed between the main screen region 440 and the light-transmitting region 460. The driving backplane 401 includes a first driving circuit 416 disposed in the transition region 450, and the first driving circuit 416 is provided with a first output terminal 456.

The driving backplane 401 further includes a driving component layer 441. In one example, the driving component layer 441 includes an active layer 437, a gate dielectric layer 413, a gate electrode layer 447, a first capacitor conductive layer 419, a capacitor dielectric layer 414, a second capacitor conductive layer 418 and an insulating dielectric layer 415.

A second driving circuit (not labeled) is disposed in the transition region 450, and the second driving circuit is provided with a second output terminal (not labeled). A third driving circuit 417 is disposed in the main screen region 440, and the third driving circuit 417 is provided with a third output terminal 457.

The driving component layer 441 provides a driving signal for a light-emitting unit in the display panel to emit light. The driving component layer 441 is a multilayer film structure. In one example, the driving component layer 441 of the transition region 450 is provided with the first driving circuit 416 and a second driving circuit (not shown). The first driving circuit 416 is provided with the first output terminal 456, and the second driving circuit is provided with a second output terminal. The driving component layer 441 disposed in the main screen region 440 is provided with the third driving circuit 417, and the third driving circuit 417 is provided with the third output terminal 457.

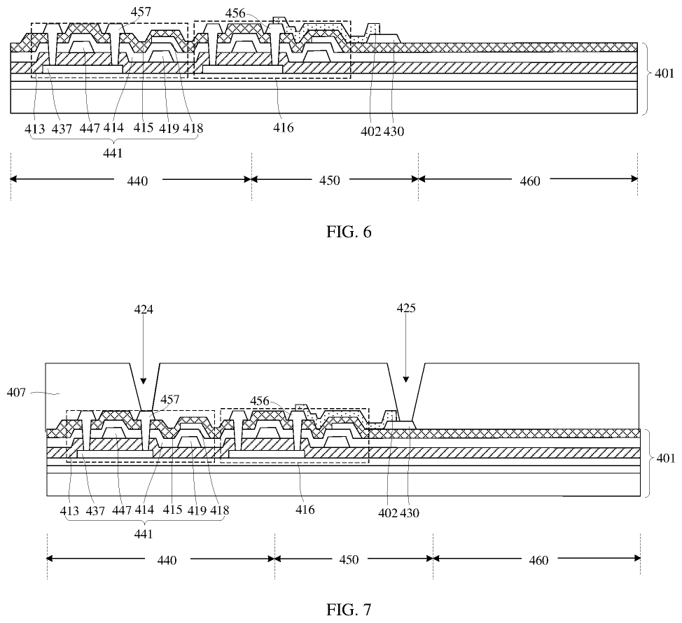

In step S2, as shown in FIG. 6, an electrical connection portion 430 is formed on the driving backplane 401; and an electrical connection layer 402 is formed on the driving backplane 401. The electrical connection layer 402 is used to realize an electrical connection between the electrical connection portion 430 and the first output terminal 456.

A sputtering process is used to form an electrical connection film, and then a part of the electrical connection film is removed by a wet etching to form a patterned electrical connection layer 402. An etching solution used in the wet etching is 5.0% oxalic acid aqueous solution.

A thickness of the electrical connection layer 402 is 280 Å to 340 Å, for example, 300 Å and 320 Å.

In step S3, as shown in FIG. 7, a planarization layer 407 is formed on the driving backplane 401 disposed in the main screen region 440, the transition region 450 and the light-transmitting region 460.

In the process steps of forming the planarization layer 407, a first through hole 425 exposing the electrical connection portion 430 is formed. That is, the first through hole 425 is formed in the first planarization layer 407 of the transition region 450, and the first through hole 425 exposes a part of a surface of the electrical connection portion 430. A second through hole is formed in the first planarization layer 407 of the transition region 450, and the second through hole exposes a part of a surface of the second output terminal. A third through hole 424 is formed in the first planarization layer 407 of the main screen region 440, and the third through hole 424 exposes a part of a surface of the third output terminal 457.

In one example, a thickness of the planarization layer 407 may be 2.1 μm.

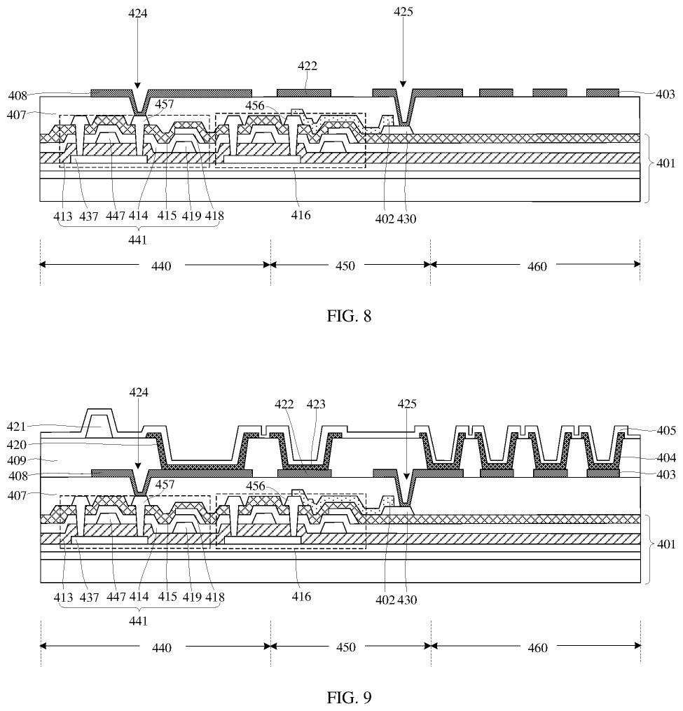

In step S4, as shown in FIG. 8, a first electrode layer 403 is formed on a side, which is facing away from the driving backplane 401, of the planarization layer 407, and the first electrode layer 403 is electrically connected with the first output terminal 456 by extending through the planarization layer 407. The first electrode layer 403 disposed in the light-transmitting region 460 includes at least two electrode blocks and an electrode bridge connecting two adjacent electrode blocks.

In one example, the first electrode layer 403 is disposed on the side, which is facing away from the driving backplane 401, of the planarization layer 407 of the transition region 450 and the light-transmitting region 460. The first electrode layer 403 is formed on a surface, which is facing away from the driving backplane 401, of the planarization layer 407 of the light-transmitting region 460, and the first electrode layer 403 also covers a bottom and a side wall of the first through hole 425. Accordingly, the first electrode layer 403 is electrically connected with the first output terminal 456 through the electrical connection layer 402.

In this embodiment, the first electrode layer 403 includes a first transparent electrode layer, a metal electrode layer, and a second transparent electrode layer which are sequentially stacked. Herein, a material of the first transparent electrode layer is ITO, and a thickness of the first transparent electrode layer is 80 Å˜120 Å, such as 90 Å, 100 Å, and 110 Å. A material of the second transparent electrode layer is ITO, and a thickness of the second transparent electrode layer is 80 Å˜120 Å, such as 90 Å, 100 Å, 110 Å. A material of the metal electrode layer is Ag or Mg, and a thickness of the metal electrode layer is 900 Åto 1100 Å, such as 950 Å, 1000 Å, or 1050 Å.

In this embodiment, in the process steps of forming the first electrode layer 403, a second electrode layer 422 disposed on the planarization layer 407 of the transition region 450 and a third electrode layer 408 disposed on the planarization layer 407 of the main screen region 440 are also formed. In this way, the process steps and manufacturing cost can be saved.

In this embodiment, a wet etching process is used to form the first electrode layer 403, the second electrode layer 422 and the third electrode layer 408. The etching liquid used in the wet etching process may be acidic solution containing HNO₃, CH₃COOH and H₃PO₄.

In step S5, as shown in FIG. 9, a plurality of first light-emitting units 404 disposed in the light-transmitting region 460 are formed, and the first light-emitting unit 404 is correspondingly disposed at a side, which is facing away from the driving backplane 401, of each electrode block. The first electrode layer 403 is used for providing electrical signals for the plurality of first light-emitting units 404.

A second light-emitting unit 423 disposed in the transition region 450 is formed, and the second electrode layer 422 is used for providing an electrical signal for the second light-emitting unit 423. A third light-emitting unit 420 disposed in the main screen region 440 is formed, and the third electrode layer 408 is used for providing an electrical signal for the third light-emitting unit 420.

Before forming the first light-emitting unit 404, the second light-emitting unit 423 and the third light-emitting unit 420, the method further includes forming a pixel defining layer 409 on the planarization layer 407.

The subsequent process steps further include: forming a supporting portion 421 on the pixel defining layer 409; and forming a cathode 405 on the first light-emitting unit 404, the second light-emitting unit 423, and the third light-emitting unit 420.

The method for manufacturing the display panel according to the embodiments uses the first electrode layer 403 to wiring for the anode of the light-transmitting region 460, which saves an ITO manufacturing process and avoids adverse effects caused by the ITO manufacturing process on the planarization layer 407 of the transition region 450 and the main screen region 440. Therefore, an Ag migration problem on the planarization layer 407 of the transition region 450 and the main screen region 440 may be avoided, thus avoiding a product abnormality problem caused by the Ag migration.

In addition, in the embodiments, it may avoid the damage to the second output terminal and the third output terminal 457 caused by the ITO process, thereby avoiding abnormal overlapping between the third electrode layer 408 and the third output terminal 457 of the main screen region 440, and avoiding abnormal overlapping between the second electrode layer 422 and the second output terminal of the transition region 450.

Moreover, the manufacturing method according to the embodiments is conducive to saving process steps, reducing manufacturing costs, and ensuring the uniformity of the optical microcavity length of the light-transmitting region 460, the transition region 450, and the main screen region 440, thereby improving the display effect of the display panel.

There is one electrode layer (i.e., the first electrode layer.) disposed between the first light-emitting unit and the planarization layer. Compared with the technical solution that there are two electrode layers between the first light-emitting unit and the planarization layer, the present embodiments removes one electrode layer, which is beneficial to simplifying the manufacturing process of the display panel and saving the cost. Furthermore, there is one electrode layer between the first light-emitting unit and the planarization layer in the present disclosure, which reduces the bombardment effect of a manufacturing process of the electrode layer on the surface of the planarization layer, improves the interface performance of the planarization layer, and further contributes to improving the quality and morphology of the first electrode layer and improving the performance of the display panel.

Those skilled in the art should appreciate that the aforementioned embodiments are specific embodiments for implementing the present disclosure. In practice, however, various changes may be made in the forms and details of the specific embodiments without departing from the spirit and scope of the present disclosure.

What is claimed is:

1. A display panel, comprising a transition region and a light-transmitting adjacent to the transition region, a light transmittance of the light-transmitting region being greater than a light transmittance of the transition region, wherein the display panel comprises:
a driving backplane comprising a first driving circuit disposed in the transition region, the first driving circuit being provided with a first output terminal;
a planarization layer disposed on the driving backplane of the transition region and the light-transmitting region;
a first electrode layer disposed at a side, facing away from the driving backplane, of the planarization layer of the transition region and the light-transmitting region, wherein the first electrode layer is electrically connected with the first output terminal by extending through the planarization layer; wherein the first electrode layer disposed in the light-transmitting region comprises at least two electrode blocks and an electrode bridge connecting two adjacent electrode blocks; and
a plurality of first light-emitting units disposed in the light-transmitting region, wherein each of the plurality of first light-emitting units is correspondingly disposed at a side, facing away from the driving backplane, of corresponding one of the at least two electrode blocks; the first electrode layer is configured to provide electrical signals for the plurality of first light-emitting units.

2. The display panel according to claim 1, wherein a cross-sectional width of the electrode bridge ranges from 1 μm to 4 μm in a direction orthogonal to a surface of the driving backplane and perpendicular to an extending direction of the electrode bridge.

3. The display panel according to claim 1, wherein an orthographic projection of the electrode bridge on the driving backplane is at least located in a region between two orthographic projections of two adjacent first light-emitting units on the driving backplane.

4. The display panel according to claim 1, wherein an orthographic projection of the first light-emitting unit on the driving backplane is larger than an orthographic projection of the electrode block corresponding to the first light-emitting unit on the driving backplane.

5. The display panel according to claim 1, wherein an area of an orthographic projection of the electrode bridge on the driving backplane is smaller than an area of an orthographic projection of the electrode block on the driving backplane.

6. The display panel according to claim 1, wherein the first electrode layer in the light-transmitting region has a zigzag shape, and each of the electrode blocks is positioned at an inflection point of the zigzag shape.

7. The display panel according to claim 6, wherein two adjacent electrode bridges of the first electrode layer are parallel, and a distance between the two adjacent electrode bridges which are parallel is greater than or equal to 5 μm.

8. The display panel according to claim 6, wherein the plurality of first light-emitting units are distributed in a zigzag shape.

9. The display panel according to claim 1, wherein the first electrode layer comprises a first transparent electrode layer, a metal electrode layer and a second transparent electrode layer which are sequentially stacked.

10. The display panel according to claim 1, wherein the display panel further comprises:
an electrical connection portion disposed at a side, facing to the driving backplane, of the planarization layer of the transition region, wherein the first electrode layer is in contact with the electrical connection portion by extending through the planarization layer; and
an electrical connection layer disposed at the side, facing to the driving backplane, of the planarization layer of the transition region, wherein the electrical connection layer is configured to electrically connect the electrical connection portion with the first output terminal.

11. The display panel according to claim 10, wherein a light transmittance of the electrical connection layer is greater than a light transmittance of the first electrode layer.

12. The display panel according to claim 1, wherein the driving backplane comprises a third driving circuit disposed in the transition region, the third driving circuit comprises a third output terminal, the display panel further comprises:
a second electrode layer disposed at a side, facing away from the driving backplane, of the planarization layer of the transition region, and the second electrode layer being electrically connected with the second output terminal by extending through the planarization layer; and
a second light-emitting unit disposed in the transition region, wherein the second light-emitting unit is disposed at a side of the second electrode layer facing away from the driving backplane, wherein the second electrode layer is configured to provide an electrical signal for the second light-emitting unit.

13. The display panel according to claim 12, wherein a material of the second electrode layer is same as a material of the first electrode layer.

14. The display panel according to claim 12, wherein the second electrode layer and the first electrode layer are arranged at a same layer.

15. The display panel according to claim 1, wherein the display panel further comprises a main screen region, the transition region is disposed between the main screen region and the light-transmitting region; the driving backplane further comprises a third driving circuit disposed in the main screen region, and the third driving circuit is provided with a third output terminal; and the display panel further comprises:
a third electrode layer disposed at a side, facing away from the driving backplane, of the planarization layer of the main screen region, wherein the third electrode layer is electrically connected with the third output terminal by extending through the planarization layer; and
a third light-emitting unit disposed in the main screen region, wherein the third light-emitting unit is disposed at a side of the third electrode layer facing away from the driving backplane, and the third electrode layer is configured to provide an electrical signal for the third light-emitting unit.

16. The display panel according to claim 15, wherein a material of the third electrode layer is same as a material of the first electrode layer.

17. The display panel according to claim 15, wherein the third electrode layer and the first electrode layer are arranged at a same layer.

18. A display device, comprising the display panel according to claim 1.
